(19) United States
(12) Patent Application Publication
(10) Pub. No.: US 2003/0173615 A1
(43) Pub. Date: Sep. 18, 2003

(54) Flash memory array integrally formed with another device and method of manufacture therefor

(76) Inventors: Kemal Tamer San, Plano, TX (US); Sunil Hattangady, McKinney, TX (US)

Correspondence Address: TEXAS INSTRUMENTS INCORPORATED, P O BOX 655474, M/S 3999, DALLAS, TX, 75265

(21) Appl. No.: 10/096,730

(22) Filed: Mar. 13, 2002

(51) Int. Cl. H01L 29/788

(52) U.S. Cl. 257/315

(57) ABSTRACT

In a workpiece for producing an apparatus having a flash memory array integrally formed with another device on a common substrate, a method for preparing the workpiece for high temperature oxidation processing permits a controllable short distance between adjacent components in the flash memory array. The workpiece includes a substrate sector configured for presenting a plurality of source elements and a plurality of drain elements for the flash memory array. The workpiece further includes a plurality of polysilicon lands arranged with the plurality of source elements and the plurality of drain elements for employment as floating gate structures in the flash memory array. The method includes the steps of: (a) growing an oxide material upon the workpiece substantially covering the workpiece; and (b) treating the oxide material with a nitrous oxide material. The treating is effected under conditions appropriate to establish a nitrogen-rich layer upon the oxide material.

### BACKGROUND OF THE INVENTION

The present invention is directed to semiconductor devices, and especially to semiconductor devices that include a plurality of devices in an integral structure on a single substrate.

In manufacturing some semiconductor apparatuses there are various sectors upon a substrate that are populated by different devices. Ultimately the various sectors and their respective devices are fashioned into a unified integral structure on the single substrate. However, during manufacture, there can be some processes used in fabricating one sector that are potentially damaging to components that have already been fabricated in another sector. Accordingly, steps must be taken to protect the already-fabricated components from the process or processes used to fabricate new components.

One example of such an apparatus includes a flash memory array integrally included in the apparatus with other devices. Sometimes in manufacturing such apparatuses the fabrication of the flash memory array has progressed to a point at which a polysilicon material has been deposited on a workpiece and fashioned or patterned to form a plurality of floating gates for the flash memory array. The next steps to be carried out in fabricating the apparatus involve steps for fashioning other devices than the flash memory array and require high temperature oxidation processes or similar processes. In such a situation there is a danger that the polysilicon floating gate structures will be oxidized, thereby ruining the already-fabricated flash memory structure.

Until now prevention of oxidation of the already-fabricated floating gate structures has been provided by depositing an oxide-nitride-oxide (ONO) multi-layer structure over the already-fabricated floating gate structures before processing other sectors in the apparatus. The ONO structure protects the already-fabricated floating gate structures from oxidation during subsequent high temperature oxidation process steps. However, the ONO layer presents problems in the finished flash memory array. Flash memory array structures require efficient voltage transfer between control gates and floating gates for efficient operation. In order to achieve desired efficiency it is desirable that the distance between control gate structures and floating gate structures be as short as possible.

The area in which the ONO layer structure is employed for protecting the floating gate structures in the flash memory array structure during fabrication of other sectors of an apparatus is situated in the interstices between the control gate structures and floating gate structures in the finished flash memory array. It is difficult enough to control the thickness of one layer of material during semiconductor processing. To control the aggregated thickness of three layers (i.e., an oxide layer, a nitride layer and an oxide layer) is extremely challenging. The difficulty in controlling thickness of the ONO structure and in minimizing that thickness is exacerbated by the cumulative error that is present. That is, there is error to be expected in thickness of the first oxide layer. Additional error is also to be expected in thickness of the nitride layer. Further error is to be expected in thickness of the final oxide layer. The three errors are cumulative in their effect. The thickness that is required for the ONO structure to effectively protect floating gate structures from oxidation during high temperature oxidation operations results in the overall thickness of the ONO structure—and therefore the distance between the control gates and floating gates of finished flash memory cells—undesirably large. The cumulative nature of the thickness variations among the ONO layers makes accurate control of the overall thickness difficult.

There is a need for a method of manufacture to produce a structure that permits protection of a workpiece in one sector of an apparatus while carrying out high temperature oxidation processes for manufacture of devices in another sector of the apparatus.

In particular, there is a need for such a method of manufacture to produce a structure that permits a predictable, controllable short distance between adjacent components in a final configuration of the device in which the protective layer is used during manufacture.

### SUMMARY OF THE INVENTION

In a workpiece for producing an apparatus having a flash memory array integrally formed with another device on a common substrate, a method for preparing the workpiece for high temperature oxidation processing permits a predictable, controllable short distance between adjacent components in a final configuration of the flash memory array. The workpiece includes a substrate sector configured for presenting a plurality of source elements and a plurality of drain elements for the flash memory array. The workpiece further includes a plurality of polysilicon lands arranged with the plurality of source elements and the plurality of drain elements for employment as floating gate structures in the flash memory array. The method includes the steps of: (a) growing an oxide material upon the workpiece substantially covering the workpiece; and (b) treating the oxide material with a nitrous oxide material. The treating is effected under conditions appropriate to establish a nitrogen-rich layer upon the oxide material.

It is, therefore, an object of the present invention to provide a method of manufacture to produce a structure that permits protection of a workpiece in one sector of an apparatus while carrying out high temperature oxidation processes for manufacture of devices in another sector of the apparatus.

It is a further object of the present invention to provide a method of manufacture to produce a structure that permits a predictable, controllable short distance between adjacent components in a final configuration of the device in which the protective layer is used during manufacture.

It is yet a further object of the present invention to provide an apparatus that is manufactured according to the method disclosed.

Further objects and features of the present invention will be apparent from the following specification and claims when considered in connection with the accompanying drawings, in which like elements are labeled using like reference numerals in the various figures, illustrating the preferred embodiments of the invention.

### BRIEF DESCRIPTION OF THE DRAWINGS

FIG. 1 is a schematic drawing illustrating salient details of construction of a prior art memory cell in a flash memory array.

FIGS. 2-12 are schematic drawings illustrating details of the configuration of an apparatus including a flash memory array according to the preferred embodiment of the method of the present invention.

FIG. 13 is a schematic drawing illustrating salient details of configuration of a memory cell in a flash memory array constructed according to the present invention.

FIG. 14 is a flow diagram illustrating the method of the present invention.

### DETAILED DESCRIPTION OF THE PREFERRED EMBODIMENT

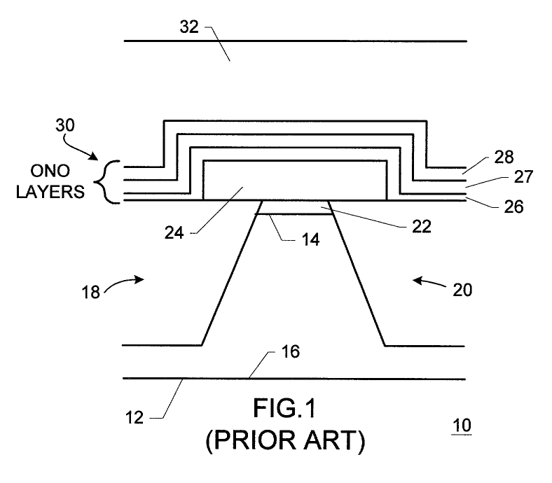

FIG. 1 is a schematic drawing illustrating salient details of construction of a prior art memory cell in a flash memory array. In FIG. 1, a memory cell 10 includes a substrate 12 having an upper face 14 and a lower face 16. A first oxide material 22 is grown upon upper face 14 of substrate 12. Well structures 18, 20 are formed in substrate 12 extending from first oxide material 22 and upper face 14 toward lower face 16. Well structure 18 may be filled with p-type material to serve, for example, as a source for memory cell 10. Well structure 20 may be filled with n-type material to serve, for example, as a drain for memory cell 10. A first polysilicon material is deposited upon first oxide material 22 and filled well structures 18, 20, then patterned to create a floating gate structure 24.

An oxide-nitride-oxide (ONO) layered structure 30 is deposited atop floating gate structure 24. ONO layered structure 30 includes a second oxide layer 26, a nitride layer 27 and a third oxide layer 28. A second polysilicon material is deposited upon ONO layered structure 30 and patterned to create a control gate structure 32. Control gate structure 32 is substantially in register with floating gate structure 24 in order to maximize electrical coupling between control gate structure 32 and floating gate structure 24. As will be well understood by those skilled in the art of flash memory cell design, electrical connections with various components of memory cell 10 are established. Exemplary such connections (not shown in FIG. 1) include a control line coupled with control gate structure 32, a source line coupled with p-type material filling well structure 18 and a bit line coupled with n-type material filling well structure 20.

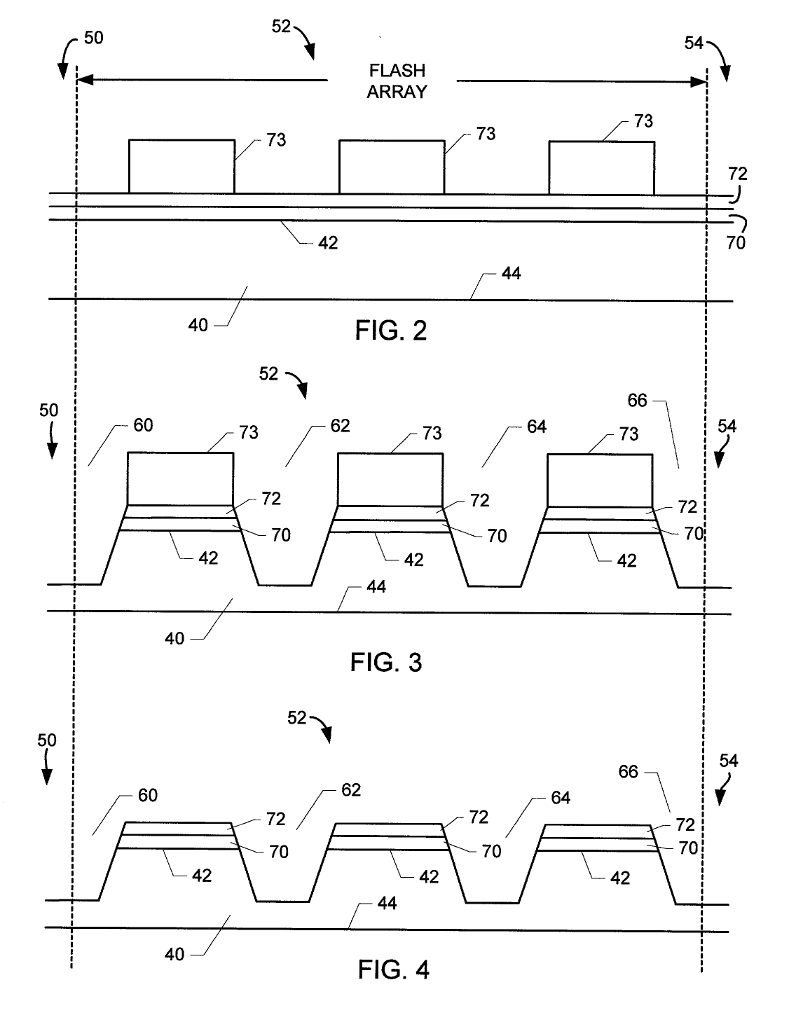

FIGS. 2-12 are schematic drawings illustrating details of the configuration of an apparatus including a flash memory array according to the preferred embodiment of the method of the present invention. In FIG. 2, a substrate 40 has an upper face 42 and a lower face 44. Substrate 40 is preferably a silicon substrate, but other substrate materials may be employed. A first oxide material 70 is deposited or grown or otherwise fashioned on upper face 42 of substrate 40. A nitride layer 72 is deposited or grown or otherwise fashioned on first oxide material 70. Photoresist material 73 is arrayed atop nitride layer 72 in a pattern related to the structure of the memory apparatus being fashioned. Substrate 40 is configured to carry more than one device and is arranged in sectors 50, 52, 54. In the finished product into which substrate 40 will be integrated (not shown in FIGS. 2-12) different devices will be fabricated in different sectors 50, 52, 54. A flash memory array will be fabricated in sector 52, as will be described.

In order to avoid prolixity, the various elements that are in common among FIGS. 2-12 will not be described repeatedly among the descriptions of the various FIGS. 2-12, except insofar as such a repeat description will aid in understanding the invention.

In FIG. 3, the assembly illustrated in FIG. 2 has been further processed and thereby patterned to establish well structures 60, 62, 64, 66 in substrate 40 extending from photoresist material 73 through nitride layer 72, first oxide layer 70 and upper face 42 toward lower face 44.

In FIG. 4, photoresist material 73 has been removed.

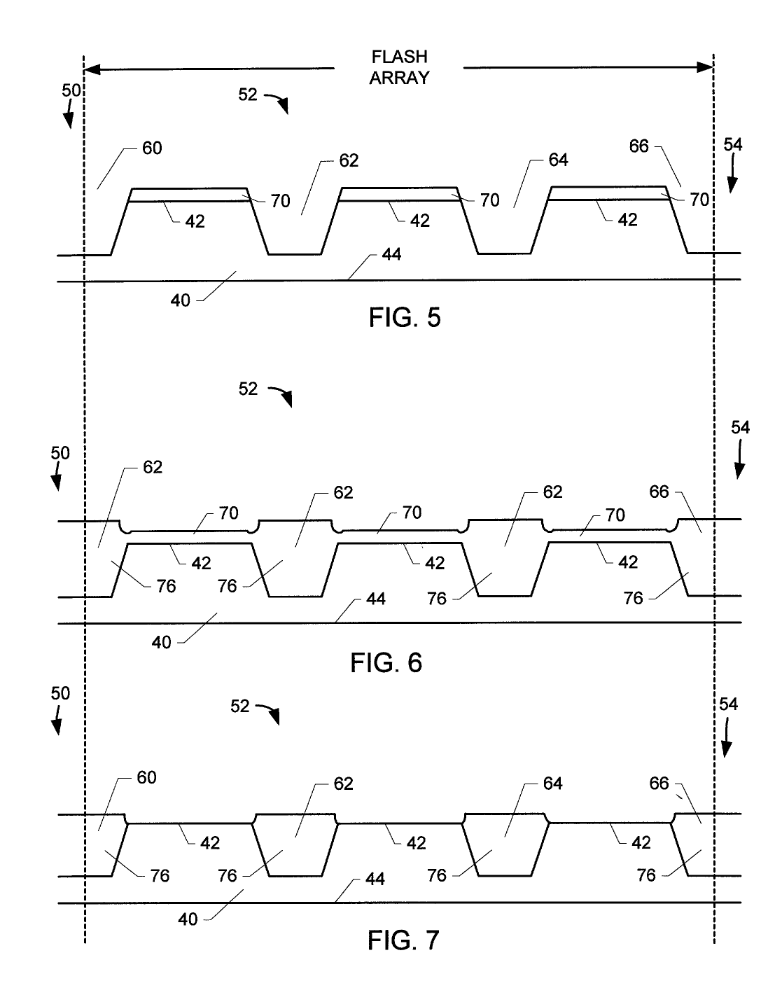

In FIG. 5, nitride layer 72 has been removed, preferably using a polishing process. The same polishing process can also be used in removing photoresist material 73.

In FIG. 6, a second oxide material 76 has been deposited or grown or otherwise fashioned in wells 60, 62, 64, 66. As a consequence, oxide materials 70, 76 constitute the entire upper layer of material upon substrate 12.

In the context of this application, the terms “deposit” and “grow” are intended to be interchangeable; no significant aspect of the present invention is substantially altered whether a deposition process or a growth process is employed in a respective method step or structural aspect.

In FIG. 7, first oxide material 70 has been removed.

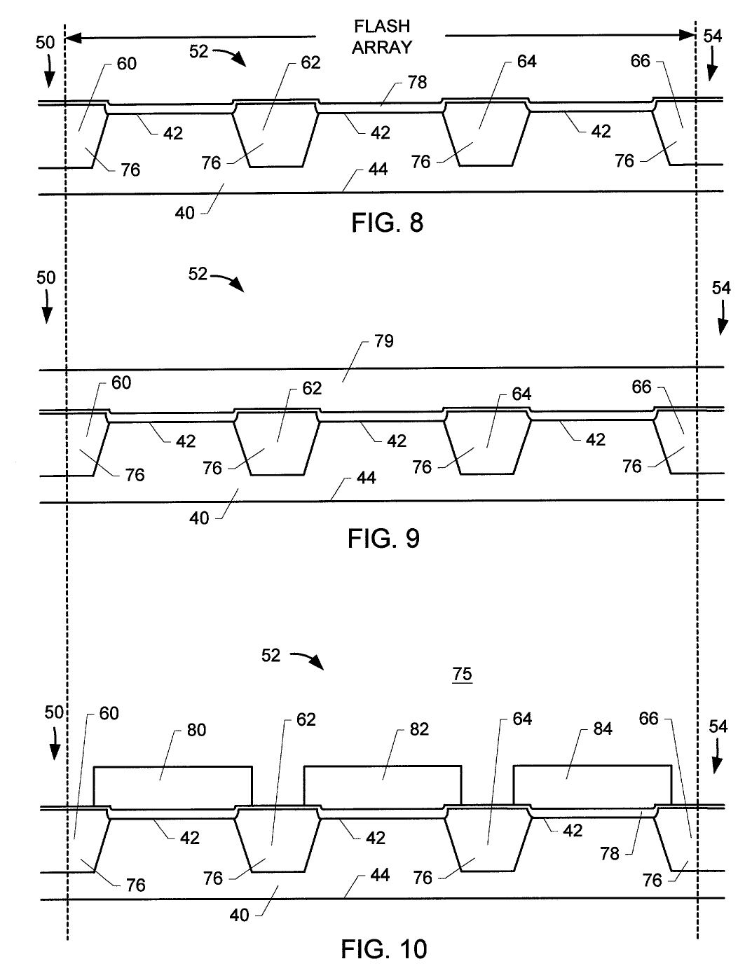

In FIG. 8, a third oxide material 78 has been deposited over the entire upper aspect of substrate 40. Third oxide material 78 thus overlies second oxide material deposits 76 in wells 60, 62, 64, 66 as well as upper faces 42 of substrate 40.

In FIG. 9, a first polysilicon material 79 is deposited upon third oxide material 78.

In FIG. 10, first polysilicon material 79 (no longer visible in FIG. 10) is patterned to establish a plurality of gate structures 80, 82, 84 and thereby establish a workpiece 75, i.e., an interim piece configured for further processing for fashioning into a finished product. Workpiece 75 includes substrate 40; second oxide material 76 in wells 60, 62, 64, 66; third oxide material 78 and floating gate structures 80, 82, 84.

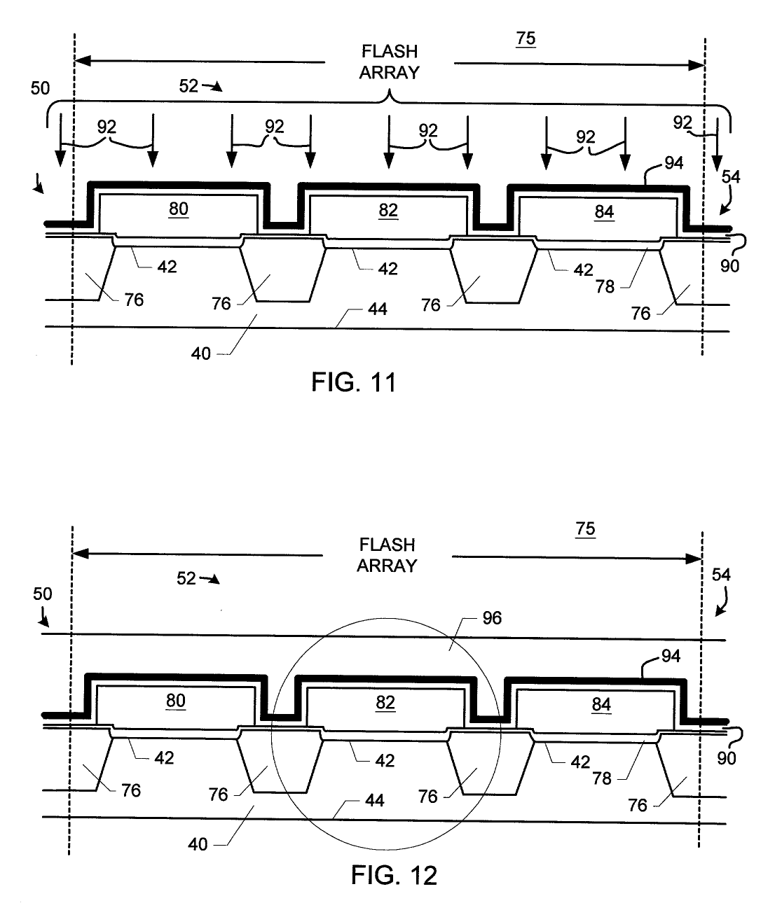

In FIG. 11, a fourth oxide material 90 is grown upon workpiece 75 preferably covering floating gate structures 80, 82, 84. Fourth oxide material 90 is subsequently treated by exposure to a nitrous oxide (NO) material, preferably in the form of NO gas, as indicated by arrows 92 in FIG. 11. Treatment of fourth oxide material 90 by NO gas establishes a nitrogen-rich layer 94 upon fourth oxide material 90 that serves to resist oxidation of fourth oxide material 90 and components beneath fourth oxide material 90 during subsequent processes to which workpiece 75 may be subjected. By way of example and not by way of limitation, sectors 50, 54 (or other sectors of workpiece 75 besides sector 52) may require high temperature oxidation processes in their manufacture. For example, a high temperature oxidation process may be required for forming gate oxides for logic array structures. Nitrogen-rich material 94 protects fourth oxide layer 90 and components beneath fourth oxide material 90 from oxidation because of such high temperature operations to which workpiece 75 may be subjected during processing of neighboring sectors of workpiece 75. Nitrogen-rich layer 94 is preferably quite thin so that the effective thickness of second oxide material 90 plus nitrogen-rich layer 94 is not substantially greater than the thickness of fourth oxide material 90 alone.

In FIG. 12, a second polysilicon material 96 been deposited over nitrogen-rich layer 94. Second polysilicon material 96 is suitable for forming control gate structures for employment in flash memory operations.

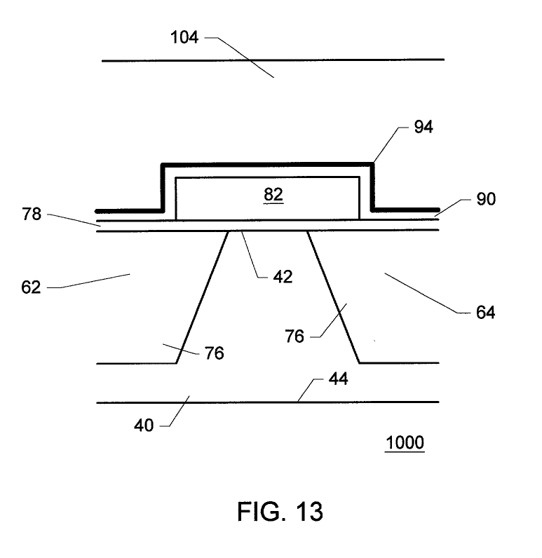

FIG. 13 is a schematic drawing illustrating salient details of configuration of a memory cell in a flash memory array constructed according to the present invention. The memory cell depicted in FIG. 13 is substantially a large-scale illustration of the area indicated by “A” in FIG. 12. Like elements in FIGS. 12 and 13 are indicated by like reference numerals in FIGS. 12 and 13. In FIG. 13, a memory cell 1000 includes a substrate 40 having an upper face 42 and a lower face 44. Substrate 40 has well structures 64, 66 extending from upper face 42 toward lower face 44. Well structures 62, 63 are filled with second oxide material 76 appropriately doped to operate as a source element or a drain element for memory cell 1000. Third oxide material 78 is situated atop substrate 40 covering well structures 62, 64 and second oxide material 76 material contained within well structures 62, 64. Floating gate structure 82 is located atop third oxide material 78 and extends over each of well structure 62, 64. Fourth oxide material 90 is deposited over floating gate structure 82 and third oxide material 78. Nitrogen-rich layer 94 is located atop fourth oxide layer 90. Nitrogen-rich layer 94 is preferably quite thin so that the effective thickness of fourth oxide material 90 plus nitrogen-rich layer 94 is not substantially greater than the thickness of fourth oxide material 90 alone.

A control gate structure 104 fashioned from second polysilicon material 96 (FIG. 12) is situated atop nitrogen-rich layer 94 substantially in register with floating gate structure 82.

An important structural feature of memory cell 1000 is the presence of only one layer of oxide material and a thin nitrogen-rich layer between floating gate structure 82 and control gate structure 104. Compared with prior art memory cell 10 (FIG. 1) in which there are three layers (ONO) between floating gate structure 24 and control gate structure 32, memory cell 1000 (FIG. 10) is much improved. The lesser distance between floating gate structure 82 and control gate structure 104 in memory cell 1000 results in improved electrical coupling between floating gate structure 82 and control gate structure 104 than was present in prior art memory cell 10 (FIG. 1). Moreover, a single oxide material layer of memory cell 1000 (FIG. 13) is more predictably and controllably manufacturable than the three-layer ONO structure of prior art memory cell 10 (FIG. 1).

To control the aggregated thickness of three layers (i.e., an oxide layer, a nitride layer and an oxide layer) in prior art memory cell 10 (FIG. 1) is extremely challenging. The difficulty in controlling thickness of the ONO structure and in minimizing that thickness is exacerbated by the cumulative error that is present. That is, there is error to be expected in thickness of the first oxide layer. Additional error is also to be expected in thickness of the nitride layer. Further error is to be expected in thickness of the final oxide layer. The three errors are cumulative in their effect. The thickness that is required for the ONO structure to effectively protect floating gate structures from oxidation during high temperature oxidation operations results in the overall thickness of the ONO structure—and therefore the distance between the control gates and floating gates of finished flash memory cells—undesirably large in prior art memory cell 10 (FIG. 1).

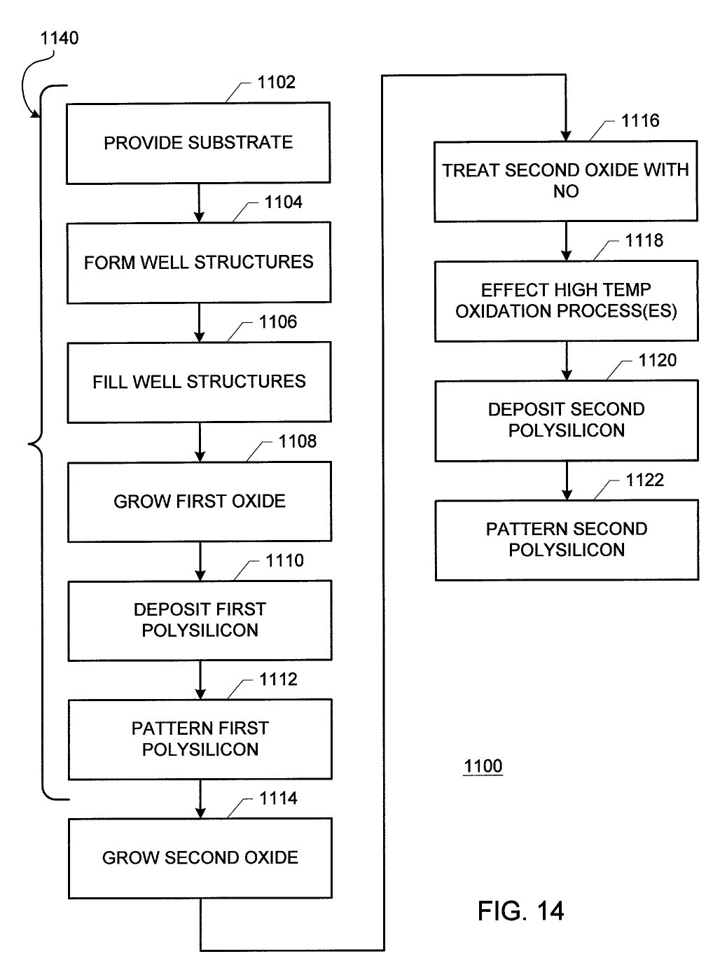

FIG. 14 is a flow diagram illustrating the method of the present invention. In FIG. 14, a method 1100 for manufacturing a flash memory device on a common substrate with at least one other apparatus is illustrated. The at least one other apparatus requires at least one high temperature oxidation process during its manufacture. Method 1100 begins with the step of providing the substrate, as indicated by a block 1102. The substrate is preferably generally planar with two substantially parallel faces and has a first oxide layer and a nitride layer carried on top of the substrate.

Method 1100 continues by forming a plurality of well structures in a substrate sector of the substrate, as indicated by a block 1104. The well structures depart from one face of the substrate to extend toward the other face of the substrate. This step may further include some additional aspects relating to removal of certain of the materials on the surface of the substrate including, for example, photoresist materials used for patterning locations for the well structures or nitride materials.

Method 1100 continues by filling the well structures in a substrate sector of the substrate, as indicated by a block 1106. First selected well structures of the plurality of well structures are filled with an oxide material to operate as source structures or to operate as drain structures for the flash memory device. Second selected well structures of the plurality of well structures are filled with an oxide material to operate as drain structures or to operate as source structures for the flash memory device.

Method 1100 continues by growing a first oxide material upon the one face of at least the substrate sector of the substrate, as indicated by a block 1108. The first oxide material preferably covers the one face within at least the substrate sector.

Method 1100 continues by depositing a first polysilicon material upon the first oxide material in at least the substrate sector, as indicated by a block 1110. Method 1100 continues by patterning the first polysilicon material to establish a workpiece having a plurality of floating gate structures for the flash memory device situated upon the first oxide material, as indicated by a block 1112. Thus, steps indicated by blocks 1102 through 1112 establish a workpiece, indicated by a collective reference numeral 1140 in FIG. 10.

Method 1100 continues by growing a second oxide material upon the workpiece, as indicated by a block 1114. The second oxide material at least substantially covers the workpiece at least in the substrate sector. Method 1100 continues by treating the second oxide layer with a nitrous oxide material, as indicated by a block 1116. Preferably the nitrous oxide material is a nitrous oxide gas. The treating is effected under conditions appropriate to establish a nitrogen-rich layer upon the second oxide material. The nitrogen-rich layer is preferably quite thin so that the effective thickness of second oxide layer plus the nitrogen-rich layer is not substantially greater than the thickness of second oxide layer alone.

Method 1100 continues by effecting an at least one high temperature oxidation process, as indicated by a block 1118. The high temperature oxidation process likely is performed on at least one device other than the flash memory device in at least one sector of the substrate other than the substrate sector in which the flash memory device is situated.

Method 1100 continues by depositing a second polysilicon material upon the nitrogen-rich layer, as indicated by a block 1120.

Method 1100 continues by patterning the second polysilicon material to establish a plurality of control gate structures in association with the plurality of floating gate structures, as indicated by a block 1122.

It is to be understood that, while the detailed drawings and specific examples given describe preferred embodiments of the invention, they are for the purpose of illustration only, that the apparatus and method of the invention are not limited to the precise details and conditions disclosed and that various changes may be made therein without departing from the spirit of the invention which is defined by the following claims:

I claim:

1. A method for manufacturing a flash memory device on a common substrate with at least one other apparatus; said at least one other apparatus requiring at least one high temperature oxidation operation during manufacture of said at least one other apparatus; the method comprising the steps of:
(a) providing said substrate; said substrate being generally planar with two substantially parallel faces;
(b) forming a plurality of well structures in a substrate sector of said substrate; said plurality of well structures departing from one face of said two faces toward the other face of said two faces;
(c) substantially filling first selected well structures of said plurality of well structures with p-type material and substantially filling second selected well structures of said plurality of well structures with n-type material; said first selected well structures to operate as source structures for said flash memory device; said second selected well structures to serve as drain structures for said flash memory device;
(d) growing a first oxide material upon said one face at least said substrate sector; said first oxide material covering said plurality of well structures and covering said one face of at least said substrate sector;
(e) depositing a first polysilicon material upon said first oxide material at least in said substrate sector;
(f) patterning said first polysilicon material to establish a workpiece having a plurality of floating gate structures for said flash memory device situated upon said first oxide material;
(g) growing a second oxide material upon said workpiece substantially covering said workpiece at least in said substrate sector;
(h) treating said second oxide material with a nitrous oxide material; said treating being effected under conditions appropriate to establish a nitrogen-rich layer upon said second oxide material;
(i) effecting said at least one high temperature oxidation operation;
(j) depositing a second polysilicon material upon said nitrogen-rich layer; and
(k) patterning said second polysilicon material to establish a plurality of control gate structures in association with said plurality of floating gate structures to complete said flash memory device.

2. A method for manufacturing a flash memory device on a common substrate with at least one other apparatus as recited in claim 1 wherein the method comprises the further step of:
(l) providing a cap layer substantially covering and insulating said flash memory device.

3. In a workpiece configured for processing to produce an apparatus having a flash memory array integrally formed with at least one other device on a common substrate, a method for preparing said workpiece for high temperature oxidation processing; said workpiece including a substrate sector configured for presenting a plurality of source elements and a plurality of drain elements for said flash memory array; said workpiece further including a plurality of polysilicon lands arranged with said plurality of source elements and said plurality of drain elements for employment as floating gate structures in said flash memory array; the method comprising the steps of:
(a) growing an oxide material upon said workpiece substantially covering said workpiece; and
(b) treating said oxide material with a nitrous oxide gas material; said treating being effected under conditions appropriate to establish a nitrogen-rich layer upon said oxide material.

4. A method for preparing a semiconductor workpiece to protect a portion of said workpiece from oxidation during subsequent high temperature oxidation processing; the method comprising the steps of:
(a) growing an oxide material at least upon said portion of said workpiece covering said portion of said workpiece; and
(b) treating said oxide material with a nitrous oxide gas material; said treating being effected under conditions appropriate to establish a nitrogen-rich layer upon said oxide material.

5. A flash memory device on a common substrate with at least one other apparatus produced by the method of claim 1.

6. A workpiece configured for processing to produce an apparatus having a flash memory array integrally formed with at least one other device on a common substrate produced by the method of claim 3.

7. A semiconductor workpiece configured to protect a portion of said workpiece from oxidation during subsequent high temperature oxidation processing produced by the method of claim 4.

8. A workpiece configured for processing to produce an apparatus; the workpiece having a sector requiring protection from oxidation during subsequent high temperature oxidation processing; the workpiece comprising:
(a) a plurality of circuit elements in said sector;
(b) an oxide layer overlaying said circuit elements; and
(c) a nitrogen-rich layer overlying said oxide layer.

9. A semiconductor apparatus comprising a plurality of circuit sectors coupled in an integrated structure; at least a first circuit sector of said plurality of circuit sectors being a flash memory array having a plurality of memory cells; each respective memory cell of said plurality of memory cells having a floating gate structure and a correspondent control gate structure; each respective said floating gate structure and correspondent control gate structure being separated buy a single layer of an oxide material.

10. A semiconductor apparatus as recited in claim 9 wherein said single layer of an oxide material includes at least remnants of a nitrogen-rich layer; said at least remnants of said nitrogen-rich layer being situated on said single layer of an oxide material in facing relation with said corresponding control gate structure.
